(19) United States
(12) Patent Application Publication
(10) Pub. No.: US 2024/0251500 A1
(43) Pub. Date: Jul. 25, 2024

(54) WIRING BOARD, MANUFACTURING METHOD OF WIRING BOARD, ELECTRONIC MODULE, ELECTRONIC UNIT, AND ELECTRONIC DEVICE

(71) Applicant: CANON KABUSHIKI KAISHA, Tokyo (JP)

(72) Inventors: HIROKI SAITO, Kanagawa (JP); TOSHIYUKI YOSHIDA, Kanagawa (JP); YU OGAWA, Tokyo (JP)

(21) Appl. No.: 18/416,591

(22) Filed: Jan. 18, 2024

(30) Foreign Application Priority Data
Jan. 24, 2023 (JP) 2023-008887

(51) Int. Cl. H05K 1/02; H04N 23/51; H04N 23/54; H05K 3/12; H05K 3/46

(52) U.S. Cl. CPC H05K 1/0219; H04N 23/54; H05K 3/1225; H05K 3/4664; H04N 23/51

(57) ABSTRACT

A wiring board includes a wiring layer and a conductive portion. The wiring layer includes a signal line. The conductive portion overlaps the wiring layer at least partially in a planar view. The conductive portion includes an irregularity shape in which a protruding portion and a recess portion are alternately arranged in a direction in which the conductive portion extends, on at least one of a first surface closer to the wiring layer, and a second surface existing on an opposite side of the first surface. A difference between a thickness of the conductive portion in the protruding portion and a thickness of the conductive portion in the recess portion is 10 micrometers (μm) or more.

### BACKGROUND

### Field

The present disclosure relates to a wiring board, a manufacturing method of a wiring board, an electronic module, an electronic unit, and an electronic device.

### Description of the Related Art

In an electronic device such as a mobile phone, a smartphone, a tablet terminal, and a digital camera, for example, a flexible wiring board serving as a transmission path of signals is used. For the purpose of improvement in electrical and/or mechanical functions, the flexible wiring board is provided with a conductive portion in addition to a signal line.

Japanese Patent Application Laid-Open No. 2015-133474 discusses a flexible circuit board in which at least one surface of an electromagnetic shield layer (conductive portion) with a thickness of 0.1 to 6 μm is roughened in such a manner as to have a roughness of 0.3 to 5 μm.

In the configuration discussed in Japanese Patent Application Laid-Open No. 2015-133474, a shield property of a wiring board has not been sufficient, and there has been room of examination in the shield property of the electromagnetic shield layer.

### SUMMARY

The present disclosure is directed to providing a wiring board with an improved shield property.

According to an aspect of the present disclosure, a wiring board includes a wiring layer including a signal line, and a conductive portion overlapping the wiring layer at least partially in a planar view, wherein the conductive portion includes an irregularity shape in which a protruding portion and a recess portion are alternately arranged in a direction in which the conductive portion extends, on at least one of a first surface closer to the wiring layer, and a second surface existing on an opposite side of the first surface, and wherein a difference between a thickness of the conductive portion in the protruding portion and a thickness of the conductive portion in the recess portion is 10 micrometers (μm) or more.

Further features of the present disclosure will become apparent from the following description of exemplary embodiments with reference to the attached drawings.

### BRIEF DESCRIPTION OF THE DRAWINGS

FIG. 1A is a perspective view of an electronic unit including a wiring board, and

FIG. 1B is a cross-sectional view of the wiring board illustrated in FIG. 1A that is taken along a B-B line.

FIG. 2 is a plan view of the wiring board.

FIG. 3A is a cross-sectional view taken along an A-A line in FIG. 2, and FIG. 3B is an enlarged view of a main part illustrated in FIG. 3A.

FIG. 4A is a plan view of a wiring board according to a second exemplary embodiment, and FIG. 4B is an enlarged view of a main part illustrated in FIG. 4A.

FIG. 5 is a schematic diagram of a system used to evaluate transmission characteristics of wiring boards according to Examples and wiring boards according to Comparative Examples.

FIG. 6 illustrates a graph indicating a relationship between an irregularity interval and a factor of a noise suppression effect in Examples.

FIG. 7 is an explanatory diagram of a digital camera being an imaging apparatus serving as an example of an electronic device according to an exemplary embodiment.

### DESCRIPTION OF THE EMBODIMENTS

Hereinafter, exemplary embodiments of the present disclosure will be described with reference to the drawings. Nevertheless, the configuration to be described below is one exemplary embodiment of the disclosure, and the present disclosure is not limited to this. In addition, common configurations will be described with reference to a plurality of drawings, and the description of configurations assigned the same reference numeral will be appropriately omitted. Different components with the same name can be distinguished from each other by adding “N-th” like a first component and a second component.

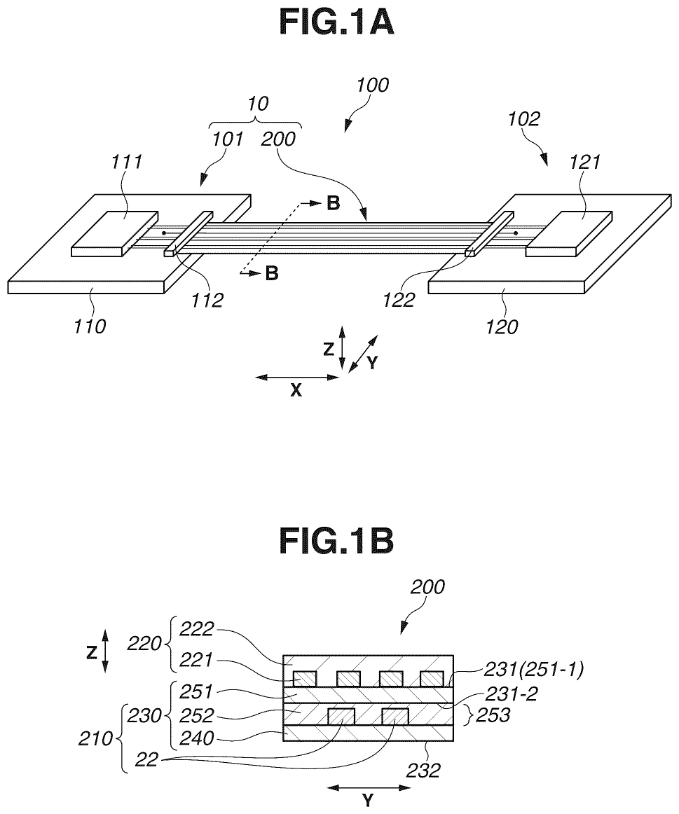

The configuration of a wiring board 200 according to a first exemplary embodiment will be described with reference to FIGS. 1A and 1B. FIG. 1A is a perspective view of an electronic unit 100 including the wiring board 200. FIG. 1B is a cross-sectional view of the wiring board 200 illustrated in FIG. 1A that is taken along a B-B line. The wiring board 200 is a flexible printed wiring board, for example. A wiring formation method on the wiring board 200 is not limited to printed wiring, and wiring may be formed using a preliminarily-formed electric cable, or the wiring board 200 may be a flat cable.

The electronic unit 100 includes circuit boards 101 and 102 and the wiring board 200 that electrically connects the circuit boards 101 and 102. The circuit boards 101 and 102 are printed circuit boards, for example. A product in which the wiring board 200 and at least either of the circuit boards 101 and 102 are connected with each other can be referred to as an electronic module 10. For example, the electronic unit 100 can be formed by preparing the electronic module 10 in which the wiring board 200 is connected to the circuit board 101, and further connecting the wiring board 200 of the electronic module 10 to the circuit board 102. In addition, by mounting various devices on the circuit board 102, an electronic device including the electronic unit 100 can be formed.

As illustrated in FIGS. 1A and 1B, the wiring board 200 extends in an X direction being a longer direction. The wiring board 200 includes a wiring layer 253 including a plurality of signal lines 22 and a ground line (not illustrated), and the signal lines 22 and the ground line extend in the X direction. The plurality of signal lines 22 and the ground line are arranged at intervals in a Y direction being a shorter direction and orthogonal to the X direction. A Z direction orthogonal to the X direction and the Y direction is a thickness direction of the wiring board 200. The wiring board 200 has flexibility and is bendable and deformable.

In the present exemplary embodiment, the plurality of signal lines 22 are entirely arranged side by side in the Y direction when viewed from the Z direction (in a planar view). Nevertheless, these signal lines 22 are only required to be arranged side by side in the Y direction at least partially in a planar view.

A connector 112 is mounted on a wiring board 110 included in the circuit board 101. The connector 112 is electrically connected to a semiconductor device 111 by a conductive pattern on the wiring board 110. Similarly to the wiring board 110, a connector 122 is mounted on a wiring board 120 included in the circuit board 102. The connector 122 is electrically connected to a semiconductor device 121 by a conductive pattern on the wiring board 120.

The wiring boards 110 and 120 are rigid wiring boards, for example, and a printed wiring board (rigid printed wiring board) including a resin board or a ceramic board can be used.

With the above-described configuration, the semiconductor devices 111 and 121 are electrically connected via the wiring board 110, the wiring board 200, and the wiring board 120 in such a manner that communication can be performed with each other. The connection to the wiring boards 110 and 120 that is to be established at the time need not be established via the connectors 112 and 122, and the wiring board 200 and the wiring boards 110 and 120 may be directly connected by soldering.

As illustrated in FIG. 1B, the signal lines 22 are provided in such a manner as to overlap a conductive portion 221 in a planar view. The conductive portion 221 is grounded by being partially connected with the ground line. The conductive portion 221 can thereby function as a shield layer that shields electromagnetic wave noise. Hereinafter, the conductive portion 221 will be sometimes referred to as a shield layer. The shield layer (conductive portion) 221 is used as a path for return current of signals passing through the signal lines 22, and constitutes a part of the ground line. The shield layer (conductive portion) 221 is only required to be arranged at a position at which the shield layer (conductive portion) 221 faces at least the signal lines 22 and the ground line, or at a position at which the shield layer (conductive portion) 221 overlaps the signal lines 22 and the ground line at least partially in a planar view.

A wiring board main body 210 includes an insulator portion 230 and a wiring layer 253. The insulator portion 230 is made of material having electrical insulation, and includes insulating layers 240, 251, and 252. The details of each insulating layer will be described below. The signal lines 22 and the ground line are made of material having conductivity. The wiring board main body 210 (i.e., the insulator portion 230, the plurality of signal lines 22, and the ground line) is formed in such a manner as to extend in the X direction.

The plurality of signal lines 22 are arranged inside the insulator portion 230 at intervals in the Y direction, but need not be always arranged inside the insulator portion 230. FIG. 1B illustrates two of the plurality of signal lines 22, but the number of signal lines 22 in the present exemplary embodiment is not limited to two, and the present exemplary embodiment is applicable to three or more signal lines 22. The insulator portion 230 is formed into a sheet shape, and has a pair of principal surfaces 231 and 232 extending in the X direction. In addition, the insulator portion 230 includes the insulating layer 252 that buries the signal lines 22 thereinside, and the insulating layers 251 and 240 that sandwich the insulating layer 252 therebetween. A shield member 220 is arranged at a position being in contact with either one of the pair of principal surfaces 231 and 232 of the insulator portion 230. In the present exemplary embodiment, the signal lines 22 are provided on the side of one surface 251-2 of the insulating layer 251, and the shield member 220 is provided on a different surface 251-1. In the present exemplary embodiment, the different surface 251-1 of the insulating layer 251 coincides with the one principal surface 231 of the insulator portion 230. The principal surface 231 can also serve as a first surface of the shield layer (conductive portion) 221, for example.

Hereinafter, each of the signal lines 22 will be described in detail. Each of the signal lines 22 is a wiring line that can be used for transmitting digital data signals. In accordance with an increase in signal transmission amount, it is desirable to form differential signal wiring lines including one set of a pair of signal lines 22 among the plurality of signal lines 22. A transmission direction in the signal lines 22 is basically the same direction among all the signal lines 22, but a signal line 22 that transmits signals in a different direction may be provided. The plurality of signal lines 22 may include a wiring line that transmits single-ended signals such as a control signal and a response signal. The thickness of the signal lines 22 is not specifically limited, but it is desirable that the thickness of the signal lines 22 is 0.1 μm or more and 20 μm or less, for example.

The formation method of the signal lines 22 is not specifically limited. For example, the signal lines 22 can be formed by a method such as metal foil bonding, metal plating, or an inkjet process. In a case where copper foils are used as metal foils, using films bonded by an adhesive or the like, a required transmission path pattern can be formed by a photolithographic etching process. In a case where the inkjet process is used, the signal lines 22 can be formed by drawing a required pattern using polymer ink containing metallic particles, and calcining the pattern at a temperature equal to or lower than a glass-transition temperature (Tg) of the insulating layer 240.

As described above, by the ground line and the shield layer (conductive portion) 221 electrically connecting with each other, the conductive portion 221 fulfills a shield function. By the wiring board 200 including the shield layer (conductive portion) 221, a shielding effect on electromagnetic wave noise radiated from the wiring board 200, and external electromagnetic wave noise conveyed to the wiring board 200 can be ensured. In this manner, by supplying a fixed potential to the shield layer (conductive portion) 221, the conductive portion 221 can have a shield function. The conductive portion 221 having the shield function can be referred to as a shield layer. A fixed potential to be supplied to the shield layer is a source potential or a grounding potential (ground potential), for example, but the fixed potential is not limited to this. The conductive portion 221 supplied with the grounding potential can be referred to as a ground layer.

Hereinafter, the shield member 220 will be described in detail. The shield member 220 is a sheet-shaped member, and includes the shield layer (conductive portion) 221, and a covering layer 222 including the shield layer (conductive portion) 221 provided thereinside. The shield layer (conductive portion) 221 is arranged at a position being in contact with the principal surface 231 of the insulator portion 230, and is only required to be arranged at a position at which the shield layer (conductive portion) 221 faces at least the signal lines 22, or at a position at which the shield layer (conductive portion) 221 overlaps the signal lines 22 at least partially in a planar view. The covering layer 222 is a protecting layer surrounding the shield layer (conductive portion) 221 in such a manner as to prevent the shield layer (conductive portion) 221 from contacting a member around the wiring board 200, and is made of material having electrical insulation.

Hereinafter, the covering layer 222 will be sometimes referred to as a protecting layer.

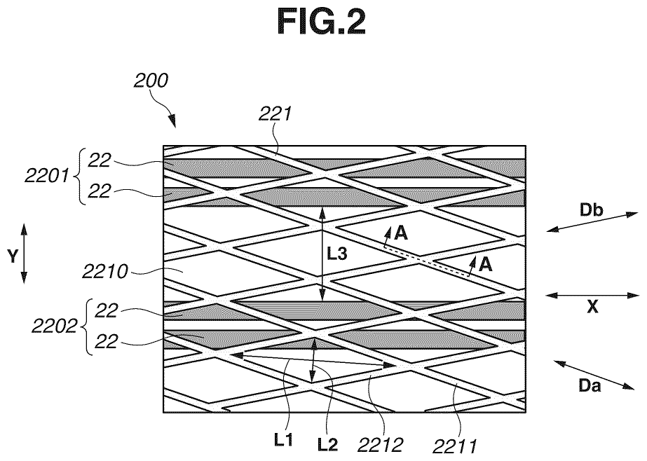

FIG. 2 is a plan view of the wiring board 200. The shield layer (conductive portion) 221 includes a plurality of lines (linear conductive portions) 2211 extending in a direction Da intersecting with the X direction being an extending direction of the signal lines 22, and a plurality of lines (linear conductive portion) 2212 extending in a direction Db intersecting with the direction Da and the X direction. That is, the shield layer (conductive portion) 221 according to the present exemplary embodiment has a configuration (mesh structure) in which a part of the shield layer (conductive portion) 221 has a grid shape, and a rhombic opening portion 2210 is provided between grids. Nevertheless, the structure of the shield layer (conductive portion) 221 according to the present exemplary embodiment is not limited to the above-described mesh structure, and the shield layer (conductive portion) 221 can have a configuration provided with a plurality of opening portions having a shape such as a circular shape, a triangular shape, a square shape, or another polygonal shape. Alternatively, a solid structure (solid electrode) in which no opening portion is provided, and the shield layer (conductive portion) 221 made of a two-dimensional continuous film is provided over the entire surface may be employed.

It is desirable that extending directions of line segments L1 and L2 connecting intersections of the lines 2211 and 2212 while striding over the opening portion 2210 are directions different from the X direction. Because this configuration can suppress a variation in impedance among the signal lines 22, it is possible to reduce a transmission failure of a digital signal to be transmitted. The line segment L2 is a line segment that intersects with the line segment L1, and is shorter than the line segment L1. It is desirable that the length of the line segment L1 is 1.5 times or more of the length of the line segment L2. In addition, it is desirable that the length of the line segment L1 is 1 mm or more and 5 mm or less. If the length of the line segment L1 is 1 mm or more and 5 mm or less, the shielding effect of electromagnetic wave noise radiated from the signal lines 22 (i.e., the wiring board 200) is enhanced. It is accordingly possible to effectively reduce electromagnetic wave noise affecting wireless communication. From the above-described viewpoint, it is desirable that the length of the line segment L1 is 1 mm or more and 5 mm or less, but the length of the line segment L1 is not limited to this.

In the present exemplary embodiment, a first differential signal wiring line 2201 and a second differential signal wiring line 2202 each including one set of differential signal wiring lines corresponding to two signal lines 22 are included. In this case, it is desirable that the length of the line segment L2 of each of the opening portions 2210 is shorter than a distance L3 between the first differential signal wiring line 2201 and the second differential signal wiring line 2202 neighboring the first differential signal wiring line 2201. The distance L3 between the first differential signal wiring line 2201 and the second differential signal wiring line 2202 is a distance between a differential signal wiring line closer to the second differential signal wiring line 2202 out of the differential signal wiring lines of the first differential signal wiring line 2201, and a differential signal wiring line closer to the first differential signal wiring line 2201 out of the differential signal wiring lines of the second differential signal wiring line 2202. This can prevent crosstalk noise from being generated between two sets of differential signal wiring lines, and prevent a failure in signal transmission.

When the wiring board 200 is planarly viewed, a ratio of the opening portion 2210 with respect to an area of the entire wiring board 200 can be defined as an opening ratio, and it is desirable that the opening ratio is 40% or more and 95% or less, and it is more desirable that the opening ratio is 50% or more and 90% or less. If the opening ratio of the shield layer (conductive portion) 221 is 40% or more (i.e., a ratio of the shield layer (conductive portion) 221 is smaller than 60%), an opening amplitude value of an eye pattern in signal transmission can be set to a sufficiently-large value, and a transmission failure of digital signals to be transmitted through the signal lines 22 can be reduced. In addition, if the opening ratio of the shield layer (conductive portion) 221 is larger than 95% (i.e., a ratio of the shield layer (conductive portion) 221 is 5% or less), it is difficult to sufficiently shield radiated noise. By the opening ratio falling within this range, it is possible to effectively reduce radiated noise radiated from the wiring board 200.

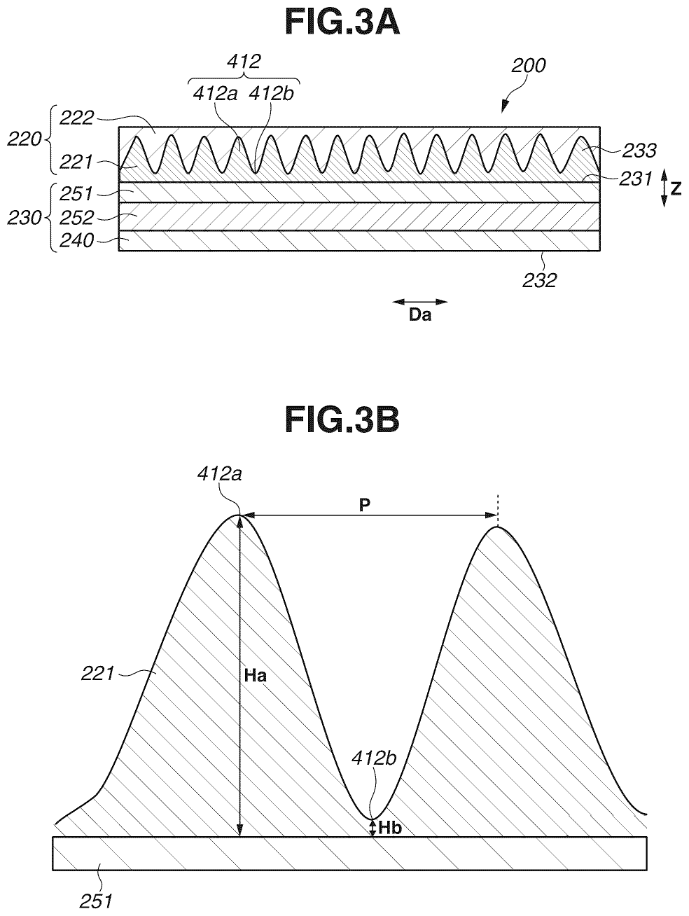

FIG. 3A is a cross-sectional view taken along an A-A line in FIG. 2, and FIG. 3B is an enlarged view of a main part illustrated in FIG. 3A. As illustrated in FIGS. 3A and 3B, a surface 233 of the shield layer (conductive portion) 221 in the wiring board 200 according to the present exemplary embodiment has an irregularity shape 412 in which protruding portions 412a and recess portions 412b are alternately arranged along the extending direction Da. That is, the irregularity shape 412 is formed by the protruding portions 412a and the recess portions 412b being alternately provided. The surface 233 is a second surface of the shield layer (conductive portion) 221, for example. A difference between a thickness Ha of the shield layer (conductive portion) 221 in the protruding portion 412a, and a thickness Hb of the shield layer (conductive portion) 221 in the recess portion 412b is 10 μm or more. By ensuring a thickness difference equal to or larger than 10 μm, it is possible to prolong a current path of noise current entering from the surface due to a skin effect. By prolonging the current path of noise current, it is possible to directly attenuate noise current, and bring out a high noise suppression effect. It is desirable that the thickness difference (Ha −Hb) is five times or more of the thickness Hb in the recess portion 412b, and it is more desirable that the thickness difference (Ha−Hb) is ten times or more. In addition, by providing the recess portions 412b, it is possible to enhance bendability of the wiring board 200 as compared with a case where the surface 233 is made flat. A specific upper limit of the thickness difference is not provided, but if the thickness difference is 150 μm or less, good noise suppression can be performed.

It is desirable that the thickness Hb of the shield layer (conductive portion) 221 in the recess portion 412b is 0.1 μm or more. In addition, it is more desirable that the thickness Hb falls within the range of 1 μm or more and 50 am or less. If the thickness Hb becomes less than 0.1 μm, the shield layer (conductive portion) 221 is torn even by slight bending of the wiring board 200, and a noise suppression effect is impaired. If the thickness Hb is 50 μm or less, the wiring board 200 can have sufficient bendability. In addition, if the thickness Hb is 50 μm or less, because the thickness of the covering layer 222 can also be made thin, it is possible to provide the wiring board 200 with higher flexibility (bendability). The thickness Ha in the protruding portion 412a is not specifically limited, but it is desirable that the thickness Ha is 10 μm or more and 200 μm or less.

It is desirable that an interval (i.e., pitch P) between the protruding portions 412a of the shield layer (conductive portion) 221 is 1 μm or more and 300 μm or less, and it is more desirable that the interval is 100 μm or less. In a case where the pitch P is too large, it might become difficult to ensure the current path of noise current, and a high noise suppression effect might fail to be brought out. It is desirable that the pitch P is larger than the thickness Hb in the recess portion 412b. As illustrated in FIG. 3B, the thicknesses Ha of the protruding portions 412a need not be uniform. In a lower part of the shield layer (conductive portion) 221, the shield layer (conductive portion) 221 is desirably continuous, but need not be always continuous. That is, a portion with the thickness Hb of 0 may exist. Nevertheless, also in this case, it is desirable that the shield layer (conductive portion) 221 is connected via a certain path, and a potential is fixed (i.e., there is no floating-state portion).

The formation method of the shield layer (conductive portion) 221 is not specifically limited. Examples of methods of forming the shield layer (conductive portion) 221 on the principal surface 231 of the insulator portion 230 illustrated in FIG. 1B include a subtractive method, an electroless plating method, an electrolysis plating method, and a physical vapor deposition method such as vacuum deposition or a sputtering method. In addition, a known coating formation method such as bar coating, slit coating, or a screen printing method can also be employed. Among these methods, it is desirable to use screen printing that can perform pattern coating using conductive material at normal temperature and under normal pressure, as a method of forming the patterned shield layer (conductive portion) 221 on the principal surface 231 of the insulator portion 230. The conductive material formed using the screen printing is made into a dry film by being heated, and the conductive portion 221 is manufactured.

Examples of the material contained in the shield layer (conductive portion) 221 include metal materials such as gold, silver, copper, aluminum, and nickel, conductive resin compositions obtained by mixing conductive fillers such as metal particles, metal fibers, and carbon nanotube into resin, and conductive polymers such as polythiophene and polypyrrole. Among these materials, silver paste containing silver particles with especially-high conductivity and a resin binder is desirably used as coating formation material. Aside from the silver paste, gold paste, copper paste, or carbon paste may be used.

In a case where the shield layer (conductive portion) 221 is formed using silver paste, it is desirable that the viscosity of the silver paste is 1 Pa·s or more and 500 Pa·s or less when a shearing speed is 10/s. By using the silver paste with the viscosity of 1 Pa·s or more, it is possible to obtain the shield layer (conductive portion) 221 with stable quality without a line width of the shield layer (conductive portion) 221 changing after the formation. By using the silver paste with the viscosity of 500 Pa·s or less, it is possible to form the shield layer (conductive portion) 221 without interruption. From the above-described viewpoint, it is more desirable that the viscosity of the silver paste is 5 to 100 Pa·s when a shearing speed is 10/s. From the viewpoint of electromagnetic wave noise shielding capability, it is desirable that electrical resistivity of the shield layer (conductive portion) 221 is 1×10 Ω·cm or less, and it is more desirable that the electrical resistivity is 1×10⁻⁵ Ω·cm or less.

Hereinafter, the insulating layers 240, 251, and 252 and the covering layer 222 that are illustrated in FIG. 1B will be described in detail.

First of all, the insulating layer 240 will be described in detail. It is desirable that the material of the insulating layer 240 serving as an insulating substrate is resin. Examples of the resin include polyimide, polyamide, and polyimide series resin such as polyamide-imide resin, thermoset resin such as epoxy resin, and thermoplastic resin such as liquid crystal polymer. Among these resins, polyimide or liquid crystal polymer is desirable. The polyimide is excellent in heat resistance and machine characteristics, and is commercially easily-available. In addition, because liquid crystal polymer has low specific inductive, liquid crystal polymer is desirably used for the purpose of transmitting high-speed signals. Liquid crystal polymer has a low hygroscopic property, and is excellent in dimensional stability.

It is desirable that the thickness in the Z direction of the insulating layer 240 is 10 μm or more and 100 μm or less, for example. By setting the thickness in the Z direction of the insulating layer 240 to 10 μm or more, it is possible to ensure a separation distance between the signal lines 22 and surrounding electronic components, and prevent characteristic impedance from varying among the signal lines 22. In addition, by setting the thickness in the Z direction of the insulating layer 240 to 100 μm or less, it is possible to lower the rigidity of the insulating layer 240, and sufficient flexibility (bendability) of the wiring board 200 can be obtained. From the above-described viewpoint, furthermore, it is more desirable that the thickness in the Z direction of the insulating layer 240 is 12 μm or more and 75 μm or less.

Next, the insulating layer 251 will be described in detail. Plastic and/or insulating resin can be used as the insulating layer 251. So-called engineering plastic is used as plastic to be used in the insulating layer 251. More specifically, examples of plastic to be used in the insulating layer 251 include polypropylene, cross-linked polyethylene, polyester, polybenzimidazole, polyamide, polyimide, polyamide-imide, and polyetherimide. In addition, examples of plastic to be used in the insulating layer 251 further include polyphenylene sulfide (PPS), polyethylene naphthalate (PEN), and polyether ether ketone (PEEK). From the viewpoint of low cost, it is desirable to use a polyester film. From the viewpoint of excellence in flame resistance, it is desirable to use a polyphenylene sulfide film. In a case where heat resistance is further required, it is desirable to use an aramid film or a polyimide film.

Insulating resin to be used in the insulating layer 251 is only required to be resin having electrical insulation, and examples include thermoset resin and ultraviolet curable resin. Examples of the thermoset resin include phenolic resin, acrylic resin, epoxy resin, melamine resin, silicone resin, and acrylic modified silicone resin. Examples of the ultraviolet curable resin include epoxy acrylate resin, polyester acrylate resin, and methacrylate modifications of these. A curing configuration may be whichever of thermal curing, ultraviolet curing, and electron radiation curing. In addition, another additive agent such as coloring pigment, a fire-retardant, an antioxidant, a lubricant agent, a dust removing agent, or a curing accelerator may be compounded as necessary.

The formation method of the insulating layer 251 is not specifically limited. In the present exemplary embodiment, the insulating layer 251 is formed by bonding the flexible insulating layer (insulating resin substrate) 251 preliminarily formed into a plate shape, onto the insulating layer (insulating substrate) 240 on which the signal lines 22 are formed, via the insulating layer (adhesion layer) 252 as described below. Aside from this, the insulating layer 251 can also be formed by coating the insulating layer 252 with insulating resin. The coating can be executed using the following methods. For example, solution obtained by dissolving insulating resin into solvent can be applied using a gravure coating method, a kiss coating method, a die coating method, a blade method, a roll coating method, a knife coating method, a spray coating method, a bar coating method, a spin coating method, or a dip coating method. Solvent can be appropriately selected depending on the type of resin to be used. For example, ketone series solvent such as acetone, methyl ethyl ketone, or cyclohexanone, or alcohol series solvent such as methanol, ethanol, propanol, ethylene glycol, glycerin, or propylene glycol monomethyl ether can be used. In addition, acid such as acetic acid, amide series solvent such as formamide, dimethyl acetamide, or N-methylpyrrolidone, nitrile series solvent such as acetonitrile or propylonitrile, or ester series solvent such as methyl acetate or ethyl acetate can be used. In addition, carbonate series solvent such as dimethyl carbonate or diethyl carbonate can also be used. When coating is executed, a heating or drying process for volatilizing solvent may be provided as necessary. In heating and drying, a heating device and a drying device such as an infrared heater and a hot air drying machine can be used, and a heating temperature and a drying temperature, and a heating time and a drying time can be appropriately selected.

It is desirable that the thickness in the Z direction of the insulating layer 251 is 5 μm or more and 50 μm or less. If the thickness in the Z direction of the insulating layer 251 is 5 μm or more, sufficient strength of the insulating layer 251 can be ensured. If the thickness in the Z direction of the insulating layer 251 is 50 μm or less, a sliding property and bendability improve. From the above-described viewpoints, furthermore, it is more desirable that the thickness in the Z direction of the insulating layer 251 is 10 μm or more and 30 μm or less. In addition, it is desirable that a volume resistivity of the insulating layer 251 is 10⁹ Ω·cm or more, and it is more desirable that the volume resistivity is 10¹³ Ω·cm or more.

Next, the insulating layer 252 will be described in detail. The insulating layer 252 is an adhesion layer provided between the insulating layer 251, and the insulating layer 240 and the signal lines 22. More specifically, the insulating layer 252 is a cured member of an adhesive. It is desirable that the insulating layer 252 has high electrical insulation. Examples of adhesives to be used to form the insulating layer 252 include acrylonitrile-butadiene rubber (NBR) series adhesive, a polyamide series adhesive, a polyester series adhesive, an acrylic series adhesive, a polyester polyurethane series adhesive, and a silicone series adhesive.

It is desirable that the insulating layer 252 can sufficiently coat each of the signal lines 22 serving as a transmission path, and is smooth. It is accordingly desirable that the thickness in the Z direction of the insulating layer 252 is 2 μm or more and 50 μm or less. If the thickness of the insulating layer 252 is 2 μm or more, an adhesive can be sufficiently buried between the signal lines 22, and the insulating layer 252 can provide bonding more firmly. In addition, if the thickness of the insulating layer 252 is 50 μm or less, it is possible to prevent an adhesive from leaking to the side from between the insulating layers 240 and 251. From the above-described viewpoint, furthermore, it is more desirable that the thickness in the Z direction of the insulating layer 252 is 5 μm or more and 30 μm or less.

The formation method of the insulating layer 252 is not specifically limited. Examples of the formation method include a method of bonding sheet-shaped adhesives and curing the adhesives, and a method of applying liquid adhesive using a dispenser or a printing method, and curing the adhesive by heat or ultraviolet.

In the present exemplary embodiment, the insulating layer 252 is assumed to be an adhesion layer that bonds the insulating layers 240 and 251, but the insulating layers 252 and 251 may be formed together by coating. In this case, these insulating layers may be separately formed, or the insulating layers 252 and 251 may be integrally formed using the same material. In a case where the insulating layers 252 and 251 are integrally formed in this manner, this configuration can be regarded as a configuration in which the insulating layer 252 or the insulating layer 251 is not provided.

Next, the covering layer 222 will be described in detail. Insulating resin to be used in the covering layer 222 is only required to be resin having electrical insulation. Examples include thermoset resin or ultraviolet curable resin, and a coating agent containing resin solution obtained by dispersing curing film components into solvent. Examples of the thermoset resin include phenol resin, acrylic resin, epoxy resin, polyamide resin, polyamide-imide resin, polyimide resin, melamine resin, silicone resin, and acrylic modified silicone resin. Examples of the ultraviolet curable resin include epoxy acrylate resin, polyester acrylate resin, and methacrylate modifications of these. Examples of the resin solution include solution obtained by dissolving polyester polyurethane resin or polyamide-imide resin into organic solvent. In addition, coloring pigment, a fire-retardant, an antioxidant, a lubricant agent, a plasticizer, a viscosity modifier, a dust removing agent, a curing accelerator, inorganic filler such as silica or carbon black, organic filler such as silicone particles or polyester particles, or another known additive agent may be compounded as necessary. Among these, a coating agent containing resin solution obtained by dispersing curing film components into solvent is desirable because contraction attributed to curing reaction is small and warping can be suppressed. Furthermore, a coating agent obtained by dissolving polyamide-imide resin having flexibility and heat resistance, into solvent is more desirable.

A known method can be selected as the formation method of the covering layer 222. For example, a method of forming a curing film by forming a film of a liquid resin composition as a coating film, such as bar coating, slit coating, spray coating, a dot dispenser, or screen printing can be used. Alternatively, a method of coating a plastic film with an adhesion component, and bonding the plastic film onto the shield layer (conductive portion) 221 via an adhesion component layer may be used. As a method of forming a curing film after a coating film is formed, a method suitable for material, such as thermal curing, ultraviolet curing, and electron radiation curing, drying by heating, or drying in a vacuum can be appropriately selected.

From the viewpoint of preventing the shield layer (conductive portion) 221 from contacting a member around the wiring board 200, it is desirable that the thickness of the covering layer 222 is larger than the thickness Hb of the shield layer (conductive portion) 221 in the recess portion 412b. It is desirable that the thickness in the Z direction of the covering layer 222 from the principal surface of the shield layer (conductive portion) 221 falls within the range of 2 μm or more and 10 μm or less. By the thickness being 2 μm or more, it is possible to effectively prevent the shield layer (conductive portion) 221 from contacting a member around the wiring board 200. In addition, by the thickness in the Z direction of the covering layer 222 from the principal surface of the shield layer (conductive portion) 221 being 10 μm or less, it is possible to effectively improve the flexibility (bendability) of the wiring board 200. From the above-described viewpoint, furthermore, it is more desirable that the thickness in the Z direction of the covering layer 222 from the principal surface of the shield layer (conductive portion) 221 is 3 μm or more and 7 μm or less.

In the exemplary embodiment described above, the irregularity shape 412 is formed on the surface of the shield layer (conductive portion) 221 that exists on the opposite side of the surface closer to the wiring layer 253 (refer to FIGS. 1B and 3A). Alternatively, the irregularity shape 412 may be formed on the surface of the shield layer (conductive portion) 221 that is closer to the wiring layer 253. In addition, irregularity shapes can also be formed on both of the surface of the shield layer (conductive portion) 221 that is closer to the wiring layer 253, and the surface existing on the opposite side of this surface.

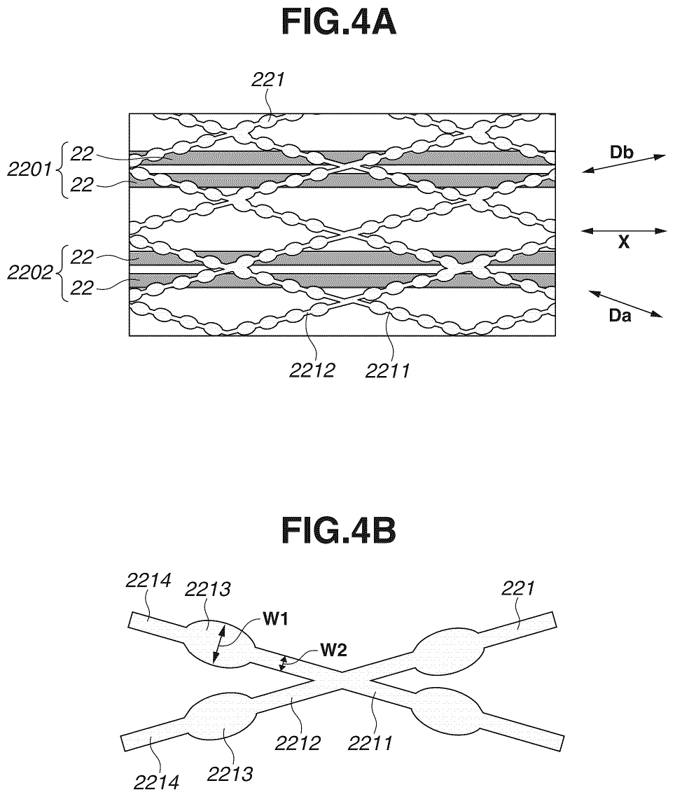

Next, a wiring board 200 according to a second exemplary embodiment will be described with reference to FIGS. 4A and 4B. FIG. 4A is a plan view of the wiring board 200 according to the present exemplary embodiment, and FIG. 4B is an enlarged view of a main part illustrated in FIG. 4A.

The wiring board 200 according to the present exemplary embodiment differs from that of the first exemplary embodiment in that a shield layer (conductive portion) 221 has a mesh structure, a line width of a line 2211 is not uniform in the direction Da, and a line width of a line 2212 is not uniform in the direction Db.

As illustrated in FIG. 4B, the lines 2211 and 2212 include a plurality of thick portions 2213 and a plurality of thin portions 2214, and a thin portion 2214 is arranged between a certain thick portion 2213 and a thick portion 2213 neighboring the certain thick portion 2213. It is desirable that the plurality of thick portions 2213 and the plurality of thin portions 2214 are alternately arranged.

The thickness in the Z direction of the conductive portion 221 becomes smaller in the thick portion 2213. In contrast, the thickness in the Z direction of the conductive portion 221 becomes larger in the thin portion 2214. That is, the thick portion 2213 corresponds to the recess portion 412b in FIG. 3B, and the thin portion 2214 corresponds to the protruding portion 412a in FIG. 3B. The formation method of the thick portion 2213 and the thin portion 2214 is not specifically limited. In the case of screen printing, the thickness in the Z direction in the thick portion 2213 can be adjusted by paste material spreading in a width direction. With this configuration, the irregularity shape 412 as described in the first exemplary embodiment can be formed.

It is desirable that a line width W1 of the thick portion 2213 is 55 μm or more and 70 μm or less, for example, and a line width W2 of the thin portion 2214 is 40 μm or more and less than 55 μm, for example. The ranges of the line width W1 and the line width W2 are not limited to the above-described ranges, and the line widths W1 and W2 are only required to be line widths different from each other. For example, it is desirable that the line width W1 is 1.1 times or more of the line width W2.

### EXAMPLES

Next, Examples and Comparative Examples will be described. Flexible printed wiring boards according to Examples correspond to the wiring board 200 according to the above-described exemplary embodiments. Hereinafter, shield properties of the flexible printed wiring boards according to Examples and flexible printed wiring boards according to Comparative Examples will be evaluated.

In Examples and Comparative Examples, a single-sided wiring board having a size with a length in the X direction being 150 mm, and a width in the Y direction being 20 mm, and including 20 sets of differential signal lines was used. The wiring board 200 according to Examples includes the wiring board main body 210 and the shield member 220. A wiring board 200X according to Comparative Examples includes the wiring board main body 210 and a shield member 220X.

The wiring board main body 210 was manufactured as follows. A copper foil with a thickness of 12 μm was stacked as a wiring layer on one surface of a base material of a polyimide film (Kapton 100H manufactured by DU PONT-TORAY CO., LTD.) with a thickness of 25 μm. After that, patterning was performed using an etching method in such a manner as to have a line width of 140 μm, a line interval of 55 am, and a total length of 120 mm, and a wiring layer that can perform differential transmission was manufactured. Subsequently, a polyimide film with a thickness of 12.5 μm and a coverlay (CISV1215 manufactured by NIKKAN INDUSTRIES Co., Ltd.) with a thickness of 15 μm were bonded onto the wiring layer, and the wiring board main body 210 was obtained.

### (1) Shield Property (Radiated Noise Measurement)

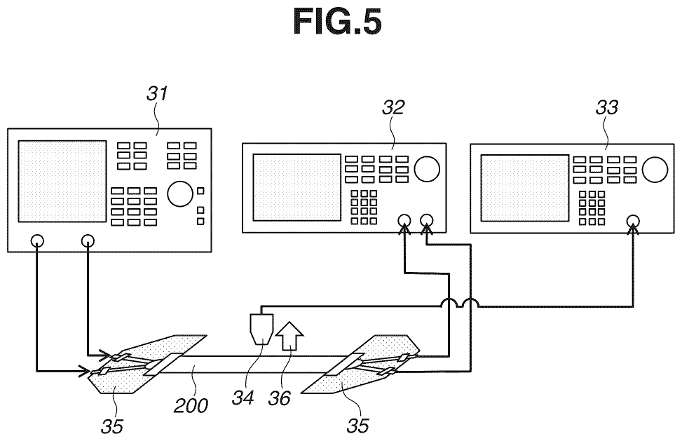

FIG. 5 is a schematic diagram of a system used to evaluate transmission characteristics of the wiring boards 200 according to Examples and the wiring boards 200X according to Comparative Examples.

First of all, a differential wiring board for measuring a radiated noise amount of a wiring board not including the shield member 220 (refer to FIG. 1B) was prepared as a reference. A copper foil with a thickness of 12 μm was stacked as a wiring layer on one surface of a base material of a polyimide film (Kapton 100H manufactured by DU PONT-TORAY CO., LTD.) with a thickness of 25 μm. After that, using an etching method, a differential transmission path with a line width of 140 am, a line interval of 55 am, and a total length of 120 mm was manufactured.

Next, a polyimide film with a thickness of 12.5 μm and a coverlay (CISV1215 manufactured by NIKKAN INDUSTRIES Co., Ltd.) with a thickness of 15 am were bonded onto the wiring layer, and a differential wiring board for reference that does not include the shield member (ground layer) was obtained.

Subsequently, this wiring board was connected to a connection board 35. Using a signal generator 31 (M8041A manufactured by Keysight Technologies), a signal having a data pattern with a bit rate of 10 Gigabit per second (Gbps) that corresponds to a pseudorandom binary sequence (PRBS) 23 was transmitted. Then, a waveform of a common mode voltage was observed using an oscilloscope 32 (92504A manufactured by Agilent Technologies, Inc.), and an input amplitude was adjusted in such a manner that the common mode voltage becomes 150 mV.

Next, a wiring board A or a wiring board B that serves as a measurement target was connected to the connection board 35, and using the signal generator 31, a signal having a data pattern with a bit rate of 10 Gbps that corresponds to the PRBS23 was transmitted. Here, the signal was transmitted with an adjusted input amplitude using the differential wiring board for reference that does not include the shield member 220. Radiated noise 36 in a 10-GHz band that was generated from the wiring board 200 at the time was detected using a near field probe 34 (manufactured by Electro-Metrics Corporation) having a pen shape and a length of 110 mm, and measured using a spectrum analyzer 33 (E4440A manufactured by Keysight Technologies). To measure a radiated noise amount, the near field probe 34 was installed at a point at the height of 5 mm from the wiring board, and scanning was performed five times for each point. After that, in a region in which the shield member 220 is formed, an average value obtained by performing all-point scanning using the near field probe 34 at 1-mm intervals was calculated as a radiated noise amount.

A difference between a noise amount of noise radiated from the wiring board for reference and noise amounts of noise radiated from the wiring board 200 and the wiring board 200X was evaluated as a shielding amount. As the shielding amount becomes larger, a shield property of a wiring board is better. The radiated noise measurement was performed at the temperature of 25° C., under the atmosphere with a relative humidity of 23 to 50%, and within a frequency range of 10 GHz.

### Example 1

The shield layer (conductive portion) 221 serving as a radiated noise shielding layer was formed on the insulating layer 251 of the wiring board main body 210. A screen printing plate including a conductive portion pattern (a line width of 65 μm, an opening ratio of 81%) with a mesh structure as illustrated in FIG. 2 was prepared, and silver paste (product name: DD-1630L-245 manufactured by Kyoto Elex Co., Ltd.) was used as the shield layer (conductive portion) 221. Printing conditions of a screen printing machine (MT-320T manufactured by Micro-tec Co., Ltd.) and a paste viscosity were adjusted, and the shield layer (conductive portion) 221 was formed on the principal surface 231 of the insulating layer 251.

As illustrated in FIG. 3B, the shield layer (conductive portion) 221 according to Example 1 includes the irregularity shape 412 on the surface 233 side in the direction (e.g., direction Da) in which the shield layer (conductive portion) 221 extends.

A difference between thicknesses in the Z direction of the protruding portion 412a and the recess portion 412b of the irregularity shape 412 is 10 μm, and the thickness of the recess portion 412b is 0.9 μm. In addition, the pitch P of the protruding portion 412a is 8 μm or less in the direction in which the shield layer (conductive portion) 221 extends. Here, the direction in which the shield layer (conductive portion) 221 extends is assumed to be the direction Da, but in a case where the shield layer (conductive portion) 221 has a solid structure, it is desirable that the direction in which the shield layer (conductive portion) 221 extends is the X direction in which the signal lines 22 extend.

Next, the covering layer 222 was formed on the shield layer (conductive portion) 221. A slit nozzle having a discharge port with a size of 0.4 mm×20 mm was prepared, and a polyamide-imide resin solution coating agent (product name: HR-16NN manufactured by Toyobo Co., Ltd.) was used as an insulating layer. Using a slit coater (SHOTMASTER300QX manufactured by Musashi Engineering, Inc.), a coating film was formed on the top surface of the shield layer (conductive portion) 221. After the coating film being promptly cured temporarily, by performing main curing for 30 minutes in a drying furnace at the atmospheric temperature of 200° C., the covering layer 222 was formed.

### Examples 2 to 4

The wiring boards 200 according to Examples 2 to 4 were formed similarly to the wiring board 200 according to Example 1 except that parameters were set as illustrated in Table 1.

### Example 5

The wiring board 200 according to Example 5 was formed similarly to the wiring board 200 according to Example 1 except that the shield layer (conductive portion) 221 has a solid structure.

### Comparative Examples 1 and 2

The wiring boards 200X according to Comparative Examples 1 and 2 were formed similarly to the wiring board 200 according to Example 1 except that parameters were set as illustrated in Table 1.

TABLE 1

| | | | | | | Comparative | Comparative |
|---|---|---|---|---|---|---|---|
| Item | Example 1 | Example 2 | Example 3 | Example 4 | Example 5 | Example 1 | Example 2 |
| Thickness | 10 | 50 | 100 | 150 | 10 | 5 | 2 |
| difference | | | | | | | |
| [μm] | | | | | | | |
| Recess | 0.9 | 2 | 5 | 7 | 0.9 | 0.8 | 1 |
| portion | | | | | | | |
| thickness | | | | | | | |
| [μm] | | | | | | | |
| Protruding | 8 | 50 | 100 | 100 | 8 | 10 | 10 |
| portion | | | | | | | |
| pitch | | | | | | | |
| [μm] | | | | | | | |
| Conductive | Mesh | Mesh | Mesh | Mesh | Solid | Mesh | Mesh |
| layer | | | | | | | |
| shape | | | | | | | |
| Radiated | 14.9 | 14.5 | 15.8 | 14.8 | 13.5 | 17.6 | 19.4 |
| noise | | | | | | | |
| amount | | | | | | | |
| [dBμV] | | | | | | | |

### (Evaluation Result)

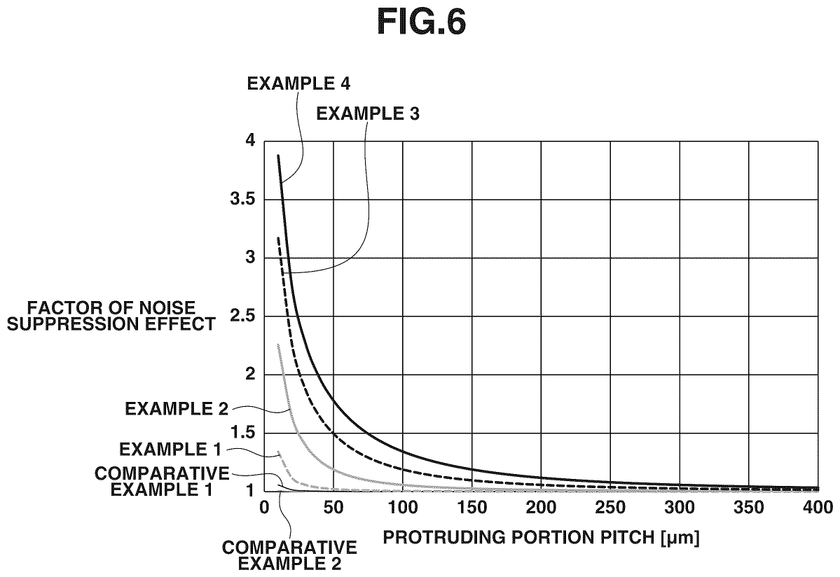

Table 1 is a table indicating evaluation results of Examples 1 to 5 and Comparatives Example 1 and 2. In Examples 1 to 5, radiated noise radiated from the wiring board 200 was small, and good values were obtained. By noise current that has failed to be cancelled out in an electromagnetical field by return current, flowing along an irregularity shape, it was able to directly attenuate noise current, and bring out a high noise suppression function. On the other hand, in Comparative Examples 1 and 2, because a difference between thicknesses in the Z direction is small, it was unable to ensure a current path sufficient for directly attenuating noise current, and a sufficient radiated noise shielding effect has failed to be obtained. As described in the present exemplary embodiment, by setting a difference between the thicknesses in the Z direction of the protruding portion 412a and the recess portion 412b to 10 μm or more, it was able to drastically reduce a radiated noise amount. FIG. 6 illustrates a graph having a horizontal axis indicating the pitch P of the protruding portion 412a and a vertical axis indicating a factor of a noise suppression effect in Examples 1 to 4 and Comparative Examples 1 and 2. Here, the factor of the noise suppression effect is a factor with respect to a noise suppression amount obtained when an irregularity shape is not provided on the top surface of the conductive portion 221 and the conductive portion 221 has a flat surface. As illustrated in FIG. 6, it can be seen that, as the pitch P of the protruding portion 412a becomes smaller, a difference in noise suppression effect that is attributed to a difference between the thicknesses in the Z direction of the protruding portion 412a and the recess portion 412b becomes more prominent.

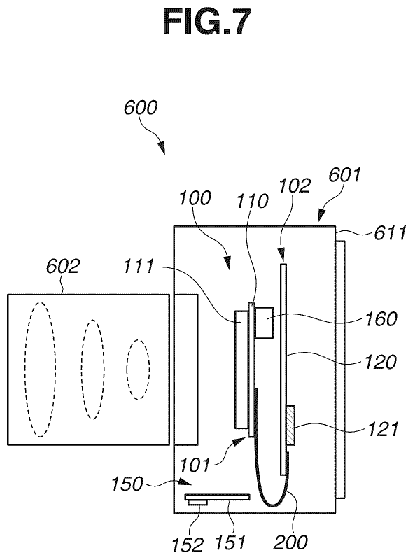

Next, as an example of an electronic device that uses any of the wiring boards 200 described in the first and second exemplary embodiments, a digital camera 600 serving as an imaging apparatus will be described with reference to FIG. 7.

The digital camera 600 is an interchangeable lens digital camera, and includes a camera main body 601. A lens unit (lens barrel) 602 including lenses is detachably attached to the camera main body 601. The camera main body 601 includes a housing 611, the electronic unit 100, and a wireless communication unit 150. The electronic unit 100 and the wireless communication unit 150 are accommodated inside the housing 611. In the case of an imaging apparatus as in the present exemplary embodiment, the electronic unit 100 is an imaging unit.

The electronic unit 100 includes the circuit boards 101 and 102 and the wiring board 200 that electrically connects the circuit boards 101 and 102. The circuit board 101 is an example of a first circuit board. The circuit board 102 is an example of a second circuit board. By using the wiring board 200 for the connection of the circuit boards 101 and 102, it is possible to save the weight of a wiring structure as compared with a coaxial cable. Here, any of the wiring boards 200 described above in the first and second exemplary embodiments is used as the wiring board 200.

The circuit board 101 includes the wiring board 110 and the semiconductor device 111 mounted on the wiring board 110. The circuit board 102 includes the wiring board 120 and the semiconductor device 121 mounted on the wiring board 120. The semiconductor devices 111 and 121 each serve as an example of an electronic component mounted on the wiring board 110 or 120. The electronic component mounted on the wiring board 110 or 120 can be an imaging apparatus, an arithmetic device, a display device, a communication apparatus, a storage device, or a power-supply apparatus. The electronic component mounted on the wiring board 110 or 120 is not limited to an active component and may be a passive component.

In the present exemplary embodiment, the semiconductor device 111 is an image sensor (imaging apparatus). The image sensor is a complementary metal oxide semiconductor (CMOS) image sensor or a charge coupled device (CCD) image sensor, for example. The image sensor has a function of converting light that has entered via the lens unit 602, into an electrical signal. In the present exemplary embodiment, the semiconductor device 121 is a processor (arithmetic device) such as a digital signal processor or an image signal processor. The image signal processor has a function of acquiring an electrical signal indicating image data, from the semiconductor device 111 serving as an image sensor (imaging apparatus), performing processing of correcting the acquired electrical signal, and generating and outputting the corrected image data. In this manner, a product in which the circuit board 101 connected to the wiring board 200 includes an image sensor can be referred to as an imaging module or an imaging unit. The imaging module is an example of an electronic module, and the imaging unit is an example of the electronic unit 100.

In the present exemplary embodiment, the electronic unit 100 includes a drive device 160 that moves the circuit board 101 (the wiring board 110 and the semiconductor device 111). The drive device 160 includes a motor serving as an example of a drive source. In the digital camera 600 including the electronic unit 100 including the drive device 160, by moving the semiconductor device 111 via the circuit board 101, it is possible to implement a camera shake correction (image stabilizer) function. The drive source in the drive device 160 is not limited to an electromagnetic motor, and may be a piezoelectric motor such as an ultrasonic motor or an electrostatic motor. In this manner, because the wiring board 200 is connected to the circuit board 101 to be moved, the wiring board 200 is required to have flexibility (bendability).

In place of the electronic unit 100 including the wiring board 200 and the circuit boards 101 and 102, a product including either of the circuit boards 101 and 102 and further including the drive device 160 and other components can also be referred to as an electronic unit.

In the present exemplary embodiment, the wiring board 200 is mounted on the digital camera 600 in a bent state, and is arranged in such a manner that the shield layer (conductive portion) 221 side becomes an external side of a curved surface. That is, the shield layer (conductive portion) 221 corresponds to the surface of the wiring board 200 that exists on the housing 611 side.

The wireless communication unit 150 performs wireless communication in a GHz band, and is modularized. The wireless communication unit 150 includes a rigid wiring board including an antenna (not illustrated) and being an example of a wiring board 151, and a wireless communication integrated circuit (IC) 152 mounted on the wiring board 151. The antenna is provided on the same surface as the wireless communication IC 152, and arranged at a position closer to the housing 611 in such a manner that communication with the outside can be easily performed. It is desirable that the wireless communication IC 152 is enabled to perform transmission and/or reception of image data by performing wireless communication with an external device such as a personal computer (PC) or a wireless router, for example, via the antenna. In the present exemplary embodiment, the wireless communication IC 152 can perform transmission and reception of data via the antenna. Specifically, the wireless communication IC 152 modulates a digital signal indicating image data that has been acquired from the semiconductor device 121, and transmits the modulated image data from the antenna as radio waves at a communication frequency of a wireless standard. In addition, the wireless communication IC 152 demodulates radio waves received via the antenna, into a digital signal indicating image data. The wireless communication IC 152 wirelessly communicates with an external device in compliance with a standard such as Wi-Fi®) or Bluetooth®, for example. In the electronic unit 100 serving as an imaging unit, if the shield layer (conductive portion) 221 provided on the wiring board 200 is used as an electromagnetic shield, it is possible to prevent electromagnetic waves emitted from the wireless communication unit 150, from generating noise in the electronic unit 100. The wiring board 200 can also be used for the connection of the wiring board 151 and another wiring board.

The exemplary embodiments described above can be appropriately modified without departing from the technical idea.

Furthermore, a plurality of exemplary embodiments can be combined. In addition, a part of the items in at least one exemplary embodiment can be deleted or replaced.

In addition, a new item can be added to at least one exemplary embodiment. The disclosure in this specification includes not only items explicitly described in this specification, but also all items that can be recognized from this specification and the drawings accompanying this specification.

The disclosure in this specification includes a complementary set of individual concepts described in this specification. More specifically, if “A is larger than B” is described in this specification, for example, even if the description “A is not larger than B” is omitted, this specification is assumed to disclose that “A is not larger than B”. This is because, in a case where “A is larger than B” is described, a case where “A is not larger than B” is assumed to be considered.

According to a wiring board according to an exemplary embodiment of the present disclosure, it is possible to improve a shield property.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-008887, filed Jan. 24, 2023, which is hereby incorporated by reference herein in its entirety.

What is claimed is:

1. A wiring board comprising:
a wiring layer including a signal line; and
a conductive portion overlapping the wiring layer at least partially in a planar view,
wherein the conductive portion includes an irregularity shape in which a protruding portion and a recess portion are alternately arranged in a direction in which the conductive portion extends, on at least one of a first surface closer to the wiring layer, and a second surface existing on an opposite side of the first surface, and
wherein a difference between a thickness of the conductive portion in the protruding portion and a thickness of the conductive portion in the recess portion is 10 micrometers (μm) or more.

2. The wiring board according to claim 1, wherein the irregularity shape is provided on the second surface of the conductive portion.

3. The wiring board according to claim 1, wherein the thickness of the conductive portion in the recess portion is 0.1 μm or more and 50 μm or less.

4. The wiring board according to claim 1, wherein the thickness of the conductive portion in the protruding portion is 10 μm or more and 200 μm or less.

5. The wiring board according to claim 1, wherein a pitch of the protruding portion in a direction in which the conductive portion extends is 100 μm or less.

6. The wiring board according to claim 1, wherein the thickness of the conductive portion in the recess portion is smaller than a pitch of the protruding portion in a direction in which the conductive portion extends.

7. The wiring board according to claim 1, wherein the difference between the thickness of the conductive portion in the protruding portion and the thickness of the conductive portion in the recess portion is five times or more of the thickness of the conductive portion in the recess portion.

8. The wiring board according to claim 1, wherein the conductive portion has a mesh structure.

9. The wiring board according to claim 8, wherein a line width of the conductive portion at a first point and a line width of the conductive portion at a second point different from the first point differ from each other.

10. The wiring board according to claim 9, wherein the line width of the conductive portion at the first point is 1.1 times or more of the line width of the conductive portion at the second point.

11. The wiring board according to claim 9, wherein the first point of the conductive portion is a point at which the recess portion is formed, and the second point of the conductive portion is a point at which the protruding portion is formed.

12. The wiring board according to claim 1, wherein the wiring board is a flexible wiring board.

13. A manufacturing method a wiring board having a wiring layer including a signal line, and a conductive portion overlapping the wiring layer at least partially in a planar view,
wherein the conductive portion includes an irregularity shape in which a protruding portion and a recess portion are alternately arranged in a direction in which the conductive portion extends, on at least one of a first surface closer to the wiring layer, and a second surface existing on an opposite side of the first surface, and
wherein a difference between a thickness of the conductive portion in the protruding portion and a thickness of the conductive portion in the recess portion is 10 micrometers (μm) or more, the manufacturing method comprising:
forming the conductive portion by screen printing.

14. An electronic module comprising:
a wiring board having a wiring layer including a signal line, and a conductive portion overlapping the wiring layer at least partially in a planar view,
wherein the wiring board is a flexible wiring board and the conductive portion includes an irregularity shape in which a protruding portion and a recess portion are alternately arranged in a direction in which the conductive portion extends, on at least one of a first surface closer to the wiring layer, and a second surface existing on an opposite side of the first surface, and
wherein a difference between a thickness of the conductive portion in the protruding portion and a thickness of the conductive portion in the recess portion is 10 micrometers (μm) or more;
a rigid wiring board to which an end portion of the flexible wiring board is connected; and
an electronic component mounted on the rigid wiring board.

15. The electronic module according to claim 14, wherein the electronic component includes an image sensor.

16. An electronic unit comprising:
the electronic module according to claim 14; and
a drive device configured to move the rigid wiring board.

17. An electronic device comprising:
the electronic module according to claim 14; and
a circuit board to which an end portion different from the end portion of the flexible wiring board is connected,
wherein a processor configured to process a signal output from the electronic component is mounted on the circuit board.

18. An electronic device comprising:
the electronic module according to claim 14; and
a housing accommodating the electronic module,
wherein the flexible wiring board is accommodated in the housing in a bent state, and
wherein the conductive portion is provided on a surface existing on an external side, out of bending surfaces of the flexible wiring board.
